(19) United States
(12) Patent Application Publication
(10) Pub. No.: US 2023/0180624 A1
(43) Pub. Date: Jun. 8, 2023

(54) MAGNETIC TUNNEL JUNCTION INCLUDING HEXAGONAL MULTI-LAYERED STRUCTURE

(71) Applicants: Samsung Electronics Co., Ltd., Suwon-si (KR); INTERNATIONAL BUSINESS MACHINES CORPORATION, Armonk, NY (US)

(72) Inventors: Sergey Faleev, Santa Clara, CA (US); Panagiotis Charilaos Filippou, Fremont, CA (US); Yari Ferrante, San Jose, CA (US); Chirag Garg, San Jose, CA (US); Mahesh Samant, San Jose, CA (US); Jaewoo Jeong, San Jose, CA (US)

(21) Appl. No.: 17/688,196

(22) Filed: Mar. 7, 2022

Related U.S. Application Data
(60) Provisional application No. 63/286,674, filed on Dec. 7, 2021.

(51) Int. Cl. H01L 43/08; H01L 43/10; H01L 43/02; G11C 11/16; H01L 27/22

(52) U.S. Cl. CPC H01L 43/08; H01L 43/10; H01L 43/02; G11C 11/161; H01L 27/222

(57) ABSTRACT

Integrated circuit devices may include a first magnetic layer, a second magnetic layer, and a tunnel barrier layer that is between the first magnetic layer and the second magnetic layer and has a hexagonal crystal structure. The first magnetic layer may include a multi-layered structure of nCo/mX that is magnetic at room temperature and has a hexagonal crystal structure, and X may be Ni, Ag, Au, Pt, Pd or Cu. n and m are each numbers of atomic layers, n may range from 0.5 to 3.5, and m may range from 0.5 to 4.5.

### CROSS-REFERENCE TO RELATED APPLICATION

This application claims priority to U.S. Provisional Application Ser. No. 63/286,674, entitled HEXAGONAL MULTILAYERS WITH PERPENDICULAR MAGNETIC ANISOTROPY AND HIGH SPIN POLARIZATION, filed in the USPTO on Dec. 7, 2021, the disclosure of which is hereby incorporated by reference herein in its entirety.

### FIELD

The present disclosure generally relates to the field of electronics and, more particularly, to magnetic tunnel junction (MTJ) structures.

### BACKGROUND

Various structures and materials of an MTJ have been developed, as the performance of devices including an MTJ may depend on properties of the MTJ. For example, a read margin, a reading speed and/or a switching speed of MRAM devices may be closely related to properties of magnetic layers and a tunnel barrier of an MTJ therein.

### SUMMARY

According to some embodiments of the present inventive concept, MTJ structures may include a first magnetic layer, a second magnetic layer, and a tunnel barrier layer that is between the first magnetic layer and the second magnetic layer and has a hexagonal crystal structure (e.g., Wurtzite structure). The first magnetic layer may include a multi-layered structure of nCo/mX that is magnetic at room temperature and has a hexagonal crystal structure, and X may be Ni, Ag, Au, Pt, Pd or Cu. n and m are each numbers of atomic layers, n may range from 0.5 to 3.5, and m may range from 0.5 to 4.5.

According to some embodiments of the present inventive concept, MRAM devices may include a substrate, a tunnel barrier layer having a Wurtzite structure, a first magnetic layer between the substrate and the tunnel barrier layer, and a second magnetic layer. The first magnetic layer may include a multi-layered structure of nCo/mX that is magnetic at room temperature and has a hexagonal crystal structure, and X may be Ni, Ag, Au, Pt, Pd or Cu. n and m are each numbers of atomic layers, n may range from 0.5 to 3.5, and m may range from 0.5 to 4.5. The tunnel barrier layer may be between the first magnetic layer and the second magnetic layer.

### BRIEF DESCRIPTION OF THE DRAWINGS

FIG. 1 is a block diagram of a MTJ structure according to some embodiments of the present invention.

FIG. 2 shows three possible positions of atoms in a single layer of a hexagonal structure.

FIGS. 3, 4 and 5 are block diagrams of memory stacks according to some embodiments of the present invention.

### DETAILED DESCRIPTION

A MTJ having high tunneling magnetoresistance (TMR) is desirable to increase a read margin and/or a reading speed. Further, a MTJ having low magnetization is desirable to increase a switching speed, as low magnetization allows to reduce a magnitude of a switching current. A magnetic layer of a MTJ, according to some embodiments of the present invention, may have large spin polarization and may provide the Brillouin Zone spin filtering effect, when coupled with a tunnel barrier layer having certain properties, thereby resulting in the MTJ having high TMR.

Further, according to some embodiments of the present invention, a magnetic layer of a MTJ may have a hexagonal crystal structure and thus may have large volume perpendicular magnetic anisotropy (PMA), which improves thermal stability of the MTJ. When a magnetic layer has volume PMA anisotropy, rather than surface (interfacial) PMA anisotropy, a device including the magnetic layer can be scaled down to have a smaller size (e.g., a smaller diameter) while maintaining thermal stability. Lowering of thermal stability due to a scale down could be compensated by increasing a thickness of the magnetic layer.

MTJ Structures

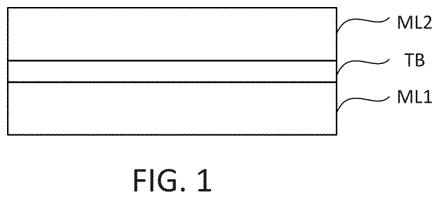

FIG. 1 is a block diagram of a MTJ structure according to some embodiments of the present invention. Referring to FIG. 1, the MTJ structure includes first and second magnetic layers ML1 and ML2 and an insulating tunnel barrier layer TB between the first and second magnetic layers ML1 and ML2. One of the first and second magnetic layers ML1 and ML2 is a free layer having a magnetization direction that can be changed (e.g., rotated) by an electrical current passing therethrough, and the other one of the first and second magnetic layers ML1 and ML2 is a reference layer having a fixed magnetization direction that cannot be changed by a current flowing therethrough.

An electrical current that tunnels between the free layer and the reference layer is spin-polarized. The magnitude of the tunneling spin-polarization is determined by a combination of the electronic properties of the free layer and the tunnel barrier layer and spin-filtering properties of a tunnel barrier layer. TMR of a MTJ structure depends on the tunneling spin-polarization of the free layer and the reference layer.

According to some embodiments of the present invention, at least one of the first and second magnetic layers ML1 and ML2 includes a magnetic layer.

An MTJ structure according to some embodiments of the present invention may be used as a data storage element of an MRAM device. The resistance of an MTJ structure varies according to relative magnetization directions of a free layer and a reference layer of the MTJ structure. When both the free layer and the reference layer have the same magnetization direction, the resistance of the MTJ is lower than when the free layer and the reference layer have different magnetization directions. In an MRAM device, data may be written by changing the resistance of an MTJ structure, and data may be read by measuring a current through the MTJ structure.

An MTJ structure according to some embodiments of the present invention may also be used as a read element of a racetrack memory device. In a racetrack memory device, data may be stored as magnetic domains along a thin strip or pillar of magnetic material, which is also referred to as a racetrack or a track, and data may be read by sensing magnetic polarities of those magnetic domains using an MTJ structure.

Further, an MTJ structure according to some embodiments of the present invention may be used as a magnetic sensor (e.g., a read head of a hard-disk drive). Magnetic field may be measured using a current through an MTJ structure, as the resistance of the MTJ structure varies according to the magnetic field applied to the MTJ structure.

Magnetic Layer

According to some embodiments of the present invention, a magnetic layer may include a multi-layered structure of nCo/mX that is magnetic at room temperature. The multi-layered structure of nCo/mX may have a hexagonal crystal structure such that the multi-layered structure has non-zero volume anisotropy and has strong PMA. In some embodiments, the multi-layered structure of nCo/mX may have a hexagonal close-packed (hcp) crystal structure and is referred to as hcp-Co/X multilayers.

X may be Ni, Ag, Au, Pt, Pd or Cu. Ni has a magnetic moment lower than Co, and Pd, Pt, Cu, Ag, and Au are non-magnetic atoms. Accordingly, the multi-layered structure of nCo/mX may have a lower magnetic moment compared to hexagonal close-packed Cobalt (i.e., hcp-Co). In some embodiments, X may be Ni, Ag, or Cu.

Each of n and m is a number of atomic layers, where n may be a real number that ranges from 0.5 to 3.5 (e.g., 0.5, 1, 1.5, 2, 2.5, 3 or 3.5), and m may be a real number that ranges from 0.5 to 4.5 (e.g., 0.5, 1, 1.5, 2, 2.5, 3, 3.5, 4 or 4.5). In some embodiments, n may range from 0.5 to 1.5 (e.g., 0.5, 1 or 1.5), and m may range from 0.5 to 4.5 (e.g., 1, 2, 3 or 4). In some embodiments, n may range from 1.5 to 2.5 (e.g., 1.5, 2 or 2.5), and m may range from 0.5 to 4.5 (e.g., 1, 2, 3 or 4). In some embodiments, n may range from 2.5 to 3.5 (e.g., 2.5, 3 or 3.5), and m may be range from 0.5 to 4.5 (e.g., 1, 2, 3 or 4). In some embodiments, X may be Ni, n may range from 0.5 to 1.5 (e.g., 0.5, 1 or 1.5), and m may range from 0.5 to 4.5 (e.g., 0.5, 1, 1.5, 2, 2.5, 3, 3.5, 4 or 4.5).

It will be understood that each of n and m can be a non-integer number due to inhomogeneity of films. For example, 2Co film may have an area having 1 or 3 atomic layers. Accordingly, as used herein, each of n and m may refer to an average number of layers. Further, it will be understood that nCo film may have a thickness (e.g., an average thickness) of about n*N, and N is a thickness of a single atomic Co layer, and mX film may have a thickness (e.g., an average thickness) of about m*M, and M is a thickness of a single atomic X layer.

According to density function theory (DFT) calculations, MTJ devices with magnetic layers ML1 and ML2 consisting of the multi-layered structures of nCo/mX are expected to have large TMR due to two effects that work synergistically: large spin polarization, and the Brillouin Zone spin filtering effect.

In some embodiments, the magnetic layer may include multiple multi-layered structures stacked on each other. In some embodiments, the magnetic layer may include 20 or fewer multi-layered structures. For example, the magnetic layer may include 10 or fewer multi-layered structures.

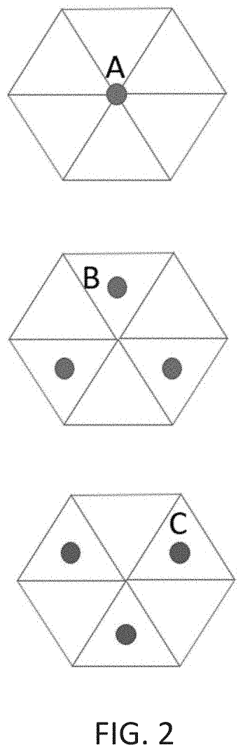

It was found that spin polarization of hexagonal multi-layered structures varies according to positions of atoms. FIG. 2 shows three possible positions of atoms in a single layer (e.g., a z-plane layer) of a hexagonal structure. Positions of atoms are marked as A, B or C. Tables 1 through 6 list positions of atoms of multi-layered structures of nCo/mX that have larger negative spin polarization than spin polarization of hcp-Co (about −0.66). For example, multi-layered structures of nCo/mX listed in Tables 1 through 6 may have spin polarization about −0.7 or less.

In the Tables, Character(s) (e.g., A, B or C) before a vertical line (“|”) represent positions of atoms of Co, and character(s) after the vertical line represent positions of atoms of X. The last character in parentheses represents positions of atoms of Co of a next nCo/mX multilayer structure. In all structures considered here, there is no identical positions of atoms in two adjacent layers: AA, BB, or CC since it is energetically prohibited. All other combinations of atoms in two adjacent layers: AB, AC, BA, BC, CA, and CB are energetically allowed.

According to Tables 1 through 6, multi-layered structures of nCo/mX have larger negative spin polarization than spin polarization of hcp-Co when both n and m are 1, and X is Ni, Ag, Pt, Pd or Cu. Further, it was found that the multi-layered structures of nCo/mX provide the Brillouin Zone spin filtering effect when both n and m are 1. The Tables 1 through 6 summarize the results of DFT calculations done with integer values of n and m. It should be noted that the results described for a particular integer value, for example I, should be applicable for a thickness range I−0.5 to I+0.5. Moreover, for person having ordinary skill in the art, it is straightforward to convert a thickness of the layer described in this form to a thickness of the layer in Angstrom.

TABLE 1
Positions of atoms of hexagonal [1-3]Co/[1-4]Ni multilayer structures

| 1Co \| 1-4Ni | 2Co \| 1-4Ni | 2Co \| 1-4Ni | 3Co \| 1-4Ni | 3Co \| 1-4Ni |
|---|---|---|---|---|
| A \| B (A) | BA \| B (A) | CA \| B (A) | ABA \| B (A) | ACA \| B (A) |
| A \| BA (B) | BA \| BA (B) | CA \| BA (B) | ABA \| BA (B) | ACA \| BA (B) |
| A \| BC (A) | BA \| BC (A) | CA \| BC (A) | ABA \| BC (A) | ACA \| BC (A) |
| A \| BAB (A) | BA \| BAB (A) | CA \| BAB (A) | ABA \| BAB (A) | ACA \| BAB (A) |
| A \| BAC (A) | BA \| BAC (A) | CA \| BAC (A) | ABA \| BAC (A) | ACA \| BAC (A) |
| A \| BCB (A) | BA \| BCB (A) | CA \| BCB (A) | ABA \| BCB (A) | ACA \| BCB (A) |
| A \| BCA (B) | BA \| BCA (B) | CA \| BCA (B) | ABA \| BCA (B) | ACA \| BCA (B) |
| A \| BABA (B) | BA \| BABA (B) | CA \| BABA (B) | ABA \| BABA (B) | ACA \| BABA (B) |
| A \| BACB (A) | BA \| BACB (A) | CA \| BACB (A) | ABA \| BACB (A) | ACA \| BACB (A) |
| A \| BCBC (A) | BA \| BCBC (A) | CA \| BCBC (A) | ABA \| BCBC (A) | ACA \| BCBC (A) |
| A \| BCAB (A) | BA \| BCAB (A) | CA \| BCAB (A) | ABA \| BCAB (A) | ACA \| BCAB (A) |
| A \| B (C) | BA \| B (C) | CA \| B (C) | ABA \| B (C) | ACA \| B (C) |
| A \| BA (C) | BA \| BA (C) | CA \| BA (C) | ABA \| BA (C) | ACA \| BA (C) |
| A \| BC (B) | BA \| BC (B) | CA \| BC (B) | ABA \| BC (B) | ACA \| BC (B) |
| A \| BAB (C) | BA \| BAB (C) | CA \| BAB (C) | ABA \| BAB (C) | ACA \| BAB (C) |
| A \| BAC (B) | BA \| BAC (B) | CA \| BAC (B) | ABA \| BAC (B) | ACA \| BAC (B) |
| A \| BCB (C) | BA \| BCB (C) | CA \| BCB (C) | ABA \| BCB (C) | ACA \| BCB (C) |
| A \| BCA (C) | BA \| BCA (C) | CA \| BCA (C) | ABA \| BCA (C) | ACA \| BCA (C) |
| A \| BABA (C) | BA \| BABA (C) | CA \| BABA (C) | ABA \| BABA (C) | ACA \| BABA (C) |
| A \| BACB (C) | BA \| BACB (C) | CA \| BACB (C) | ABA \| BACB (C) | ACA \| BACB (C) |
| A \| BCBC (B) | BA \| BCBC (B) | CA \| BCBC (B) | ABA \| BCBC (B) | ACA \| BCBC (B) |
| A \| BCAB (C) | BA \| BCAB (C) | CA \| BCAB (C) | ABA \| BCAB (C) | ACA \| BCAB (C) |

It was found that nCo/mNi multilayer structures have average magnetic moment per atom (e.g., about 0.8μ_{B}) lower than a magnetic moment of hcp-Co (about 1.6μ_{B}) when n is 1 and m is 1, 2, 3 or 4.

TABLE 2
Positions of atoms of hexagonal [1-3]Co/[1-4]Pd multilayer structures

| 1Co \| 1-4Pd | 2Co \| 1-4Pd | 2Co \| 1-4Pd | 3Co \| 1-4Pd | 3Co \| 1-4Pd |
|---|---|---|---|---|
| A \| B (A) | BA \| B (A) | CA \| B (A) | ABA \| B (A) | ACA \| B (A) |
| A \| BA (B) | BA \| BA (B) | CA \| BA (B) | ABA \| BA (B) | ACA \| BA (B) |
| A \| BC (A) | BA \| BC (A) | CA \| BC (A) | ABA \| BC (A) | ACA \| BC (A) |
| A \| BAB (A) | | | ABA \| BAB (A) | ACA \| BAB (A) |
| | | | ABA \| BAC (A) | ACA \| BAC (A) |
| A \| BCB (A) | | | ABA \| BCB (A) | ACA \| BCB (A) |
| A \| BCA (B) | | CA \| BCA (B) | ABA \| BCA (B) | ACA \| BCA (B) |
| | | | ABA \| BABA (B) | ACA \| BABA (B) |
| | BA \| BACB (A) | | | |
| | | CA \| BCBC (A) | | |
| | | CA \| BCAB (A) | | |
| A \| B (C) | BA \| B (C) | CA \| B (C) | ABA \| B (C) | ACA \| B (C) |
| A \| BA (C) | BA \| BA (C) | CA \| BA (C) | ABA \| BA (C) | ACA \| BA (C) |
| A \| BC (B) | BA \| BC (B) | CA \| BC (B) | ABA \| BC (B) | ACA \| BC (B) |
| | | | ABA \| BAB (C) | ACA \| BAB (C) |
| A \| BAC (B) | | | ABA \| BAC (B) | ACA \| BAC (B) |
| | BA \| BCB (C) | CA \| BCB (C) | ABA \| BCB (C) | ACA \| BCB (C) |
| A \| BCA (C) | | | ABA \| BCA (C) | ACA \| BCA (C) |
| | | | | ACA \| BABA (C) |
| | | | | ACA \| BCBC (B) |
| | | CA \| BCAB (C) | | |

It was found that nCo/mPd multilayer structures have average magnetic moment per atom (e.g., about 0.72μ_{B}) lower than a magnetic moment of hcp-Co (about 1.6μ_{B}) when n is 1 and m is 1, 2, 3 or 4.

TABLE 3
Positions of atoms of hexagonal [1-3]Co/[1-
4]Cu multilayer structures

| 1Co \| 1-4Cu | 3Co \| 1-4Cu | 3Co \| 1-4Cu |
|---|---|---|
| A \| B (A) | ABA \| B (A) | ACA \| B (A) |
| | ABA \| BA (B) | ACA \| BA (B) |
| | ABA \| BC (A) | ACA \| BC (A) |
| | ABA \| BAB (A) | |
| A \| B (C) | | ACA \| B (C) |
| | ABA \| BA (C) | ACA \| BA (C) |
| | ABA \| BC (B) | ACA \| BC (B) |
| | ABA \| BABA (C) | |
| | ABA \| BCAB (C) | |

It was found that nCo/mCu multilayer structures have average magnetic moment per atom (e.g., about 0.78μ_{B}) lower than a magnetic moment of hcp-Co (about 1.6μ_{B}) when n is 1 and m is 1.

TABLE 4
Positions of atoms of hexagonal [1-3]Co/[1-
4]Ag multilayer structures

| 1Co \| 1-4Ag | 3Co \| 1-4Ag | 3Co \| 1-4Ag |
|---|---|---|
| A \| B (A) | ABA \| B (A) | ACA \| B (A) |
| A \| BA (B) | ABA \| BA (B) | ACA \| BA (B) |
| A \| BC (A) | ABA \| BC (A) | ACA \| BC (A) |
| | ABA \| BAB (A) | ACA \| BAB (A) |
| | ABA \| BAC (A) | |
| | ABA \| BCB (A) | |
| | ABA \| BCA (B) | ACA \| BCA (B) |
| | ABA \| BABA (B) | ACA \| BABA (B) |
| | ABA \| BACB (A) | |
| | ABA \| BCBC (A) | |
| | ABA \| BCAB (A) | |
| A \| B (C) | ABA \| B (C) | ACA \| B (C) |
| A \| BA (C) | ABA \| BA (C) | ACA \| BA (C) |
| A \| BC (B) | ABA \| BC (B) | ACA \| BC (B) |
| | ABA \| BAB (C) | ACA \| BAB (C) |
| | ABA \| BAC (B) | |
| | ABA \| BCB (C) | ACA \| BCB (C) |
| | ABA \| BCA (C) | |
| | ABA \| BACB (C) | |
| | ABA \| BCBC (B) | |
| | ABA \| BCAB (C) | ACA \| BCAB (C) |

It was found that nCo/mAg multilayer structures have average magnetic moment per atom (e.g., about 0.85μ_{B}) lower than a magnetic moment of hcp-Co (about 1.6μ_{B}) when n is 1 and m is 1, 2, 3 or 4.

TABLE 5
Positions of atoms of hexagonal [1-3]Co/[1-
4]Au multilayer structures

| 1Co \| 1-4Au | 2Co \| 1-4Au | 3Co \| 1-4Au | 3Co \| 1-4Au |
|---|---|---|---|
| | | ABA \| B (A) | ACA \| B (A) |
| A \| BA (B) | | ABA \| BA (B) | ACA \| BA (B) |
| A \| BC (A) | | ABA \| BC (A) | ACA \| BC (A) |
| | | ABA \| BAB (A) | ACA \| BAB (A) |
| A \| BAC (A) | | | ACA \| BAC (A) |
| A \| BCB (A) | | ABA \| BCB (A) | ACA \| BCB (A) |
| A \| BCA (B) | | ABA \| BCA (B) | ACA \| BCA (B) |
| | | ABA \| BABA (B) | ACA \| BABA (B) |
| | | ABA \| BACB (A) | |
| | CA \| BCAB (A) | | |
| A \| B (C) | | ABA \| B (C) | ACA \| B (C) |
| A \| BA (C) | | ABA \| BA (C) | ACA \| BA (C) |
| | | ABA \| BC (B) | ACA \| BC (B) |
| A \| BAB (C) | | ABA \| BAB (C) | ACA \| BAB (C) |
| A \| BAC (B) | | ABA \| BAC (B) | ACA \| BAC (B) |
| A \| BCB (C) | | ABA \| BCB (C) | ACA \| BCB (C) |
| A \| BCA (C) | | ABA \| BCA (C) | ACA \| BCA (C) |
| | | ABA \| BABA (C) | |
| | | ABA \| BACB (C) | |
| | | ABA \| BCBC (B) | |
| | CA \| BCAB (C) | ABA \| BCAB (C) | |

It was found that nCo/mAu multilayer structures have average magnetic moment per atom (e.g., about 0.45μ_{B}) lower than a magnetic moment of fhcp-Co (about 1.6μ_{B}) when n is 1 and m is 1, 2, 3 or 4.

TABLE 6
Positions of atoms of hexagonal [1-3]Co/[1-
4]Pt multilayer structures

| 1Co \| 1-4Pt | 2Co \| 1-4Pt | 3Co \| 1-4Pt | 3Co \| 1-4Pt |
|---|---|---|---|
| A \| B (A) | | ABA \| B (A) | ACA \| B (A) |
| A \| BA (B) | CA \| BA (B) | ABA \| BA (B) | |
| A \| BC (A) | CA \| BC (A) | ABA \| BC (A) | |
| | | ABA \| BAB (A) | |
| | | | ACA \| BAC (A) |
| A \| B (C) | | ABA \| B (C) | ACA \| B (C) |
| A \| BA (C) | | | ACA \| BA (C) |
| A \| BC (B) | | | ACA \| BC (B) |
| | | | ACA \| BAB (C) |
| | | ABA \| BAC (B) | |
| | | ABA \| BCB (C) | |

It was found that nCo/mPt multilayer structures have average magnetic moment per atom (e.g., about 0.87μ_{B}) lower than a magnetic moment of hcp-Co (about 1.6μ_{B}) when n is 1 and m is 1, 2, 3 or 4.

Tunnel Barrier Layer

A tunnel barrier layer, according to some embodiments of the present invention, may further enhance tunneling spin polarization, thereby further reducing a magnitude of a switching current. Further, a tunnel barrier layer, according to some embodiments of the present invention, may allow the magnetic layer to provide the Brillouin Zone spin filtering effect.

In some embodiments, a tunnel barrier layer may have a certain symmetry such that the Brillouin Zone spin filtering effect happens. For example, a tunnel barrier layer may have a hexagonal crystal structure (e.g., a Wurtzite structure). Further, a tunnel barrier layer may have F-point focusing property to provide a high filtering effect. A tunnel barrier layer has F-point focusing property if the lowest attenuation constant is at the Γ-point of the 2D Brillouin Zone, and transmission through this tunnel barrier layer will be dominated by an increasingly smaller area of the 2D Brillouin Zone in a vicinity of the Γ-point when a thickness of the tunnel barrier layer increases.

Further, a tunnel barrier layer may satisfy lattice matching conditions described in Equation (1).

α_{barrier}=α,2α/\sqrt{3},\sqrt{3}α, or 2α (1)

α_{barrier} is a lattice constant of a tunnel barrier layer

α is a lattice constant of the multi-layered structure of nCo/mX

In some embodiments, a lattice constant of a tunnel barrier layer may range from 90% to 110% of a lattice constant of the multi-layered structure of nCo/mX. When a lattice constant of a tunnel barrier layer is in this range, lattices of the tunnel barrier layer and the multi-layered structure of nCo/mX can be matched after the tunnel barrier layer and the multi-layered structure of nCo/mX are formed.

The tunnel barrier layer may be, for example, AlN, GaN, CdS, CdSe, MgSe, or MgTe.

Memory Stack

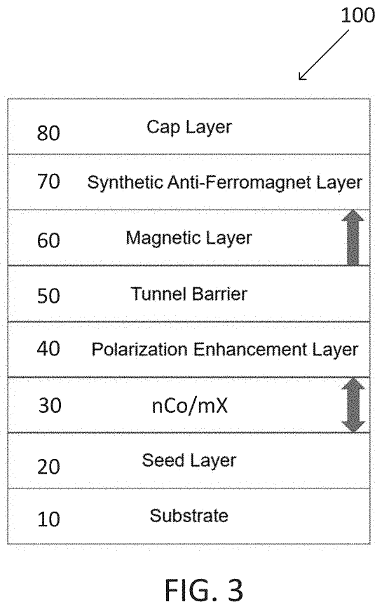

FIGS. 3, 4 and 5 show block diagrams of memory stacks according to some embodiments of the present invention. Referring to FIG. 3, a memory stack 100 may include a free layer 30 including a multi-layered structure of nCo/mX according to some embodiments of the present invention. The memory stack 100 may also include a substrate 10 and a seed layer 20 between the substrate 10 and the free layer 30. In some embodiments, the free layer 30 may contact the seed layer 20 such that the free layer 30 may be grown from the seed layer 20. The free layer 30 may include, for example, 20 or fewer (e.g., 10 or fewer) multi-layered structures of nCo/mX stacked on the substrate 10.

The substrate 10 may be a bottom electrode layer and may include, for example, Ta or other conductive layers. The seed layer 20 may include, for example, NiCr, NiFe, or NiFeCr.

A tunnel barrier layer 50 of the memory stack 100 may be AlN, GaN, CdS, CdSe, MgSe, or MgTe. Optionally, a polarization enhancement layer 40 may be provided between the free layer 30 and the tunnel barrier layer 50. The polarization enhancement layer 40 may include multiple magnetic layers.

The memory stack 100 may further include a reference layer 60 including a magnetic layer, and the reference layer 60 may contact the tunnel barrier layer 50. Optionally, a synthetic anti-ferromagnetic layer 70 may be provided on the reference layer 60. The reference layer 60 may include, for example, Fe, a CoFe alloy, or a CoFeB alloy, and may contact the synthetic anti-ferromagnetic layer 70. The magnetic moment of the reference layer 60 may be stabilized to a high magnetic field (i.e., its coercivity may be made significantly higher than the coercivity of the free layer 30) due to interaction with the synthetic anti-ferromagnetic layer 70. The synthetic anti-ferromagnetic layer 70 may include two magnetic layers coupled to each other via a separation layer which may include, for example, Ru, Ir and/or Rh.

A capping layer 80 may be provided on the synthetic anti-ferromagnetic layer 70. The capping layer 80 may include, for example, Mo, W, Ta and/or Ru. The magnetic layer 30 of FIG. 3 may be nCo/mX multilayer.

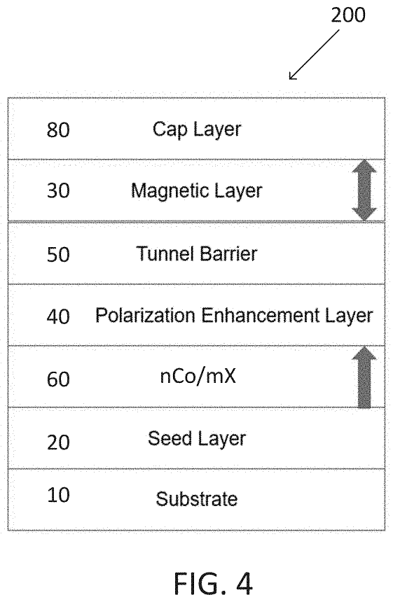

Referring to FIG. 4, a memory stack 200 may include a reference layer 60 including a multi-layered structure of nCo/mX according to some embodiments of the present invention. The reference layer 60 may include, for example, 20 or fewer (e.g., 10 or fewer) multi-layered structures of nCo/mX stacked on the substrate 10. The memory stack 200 may be substantially the same as the memory stack 100 with a primary difference being that the synthetic anti-ferromagnetic layer 70 placed overlaying magnetic layer 30 above the tunnel barrier layer 50 of the memory stack 100 is omitted. A free layer 30 including a magnetic layer may be provided on a tunnel barrier layer 50 and may contact a capping layer 80. Although not shown in FIG. 4, in some embodiments, a synthetic antiferromagnet layer may be placed between the seed layer 20 and the reference layer 60.

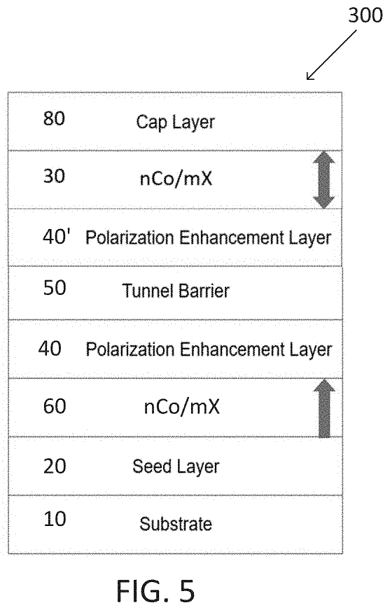

Referring to FIG. 5, a memory stack 300 may include a reference layer 60 and a free layer 30, each of which includes a multi-layered structure of nCo/mX according to some embodiments of the present invention. The memory stack 300 may be substantially the same as the memory stack 200 with primary differences being that the free layer 30 also includes a multi-layered structure of nCo/mX, and an additional polarization enhancement layer 40′ is provided between a tunnel barrier layer 50 and the free layer 30. Although not shown in FIG. 5, in some embodiments, a synthetic antiferromagnet layer may be placed between the seed layer 20 and the reference layer. 60. The multi-layered structures of nCo/mX of the reference layer 60 and the free layer 30 may be the same as or different from each other. For example, the reference layer 60 may include a multi-layered structure of nCo/mX, and the free layer 30 may include a multi-layered structure of n′Co/m′X′ that is magnetic at room temperature and has a hexagonal crystal structure. X′ is Ni, Ag, Au, Pt, Pd or Cu and may be the same as or different from X. n′ and m′ are each numbers of atomic layers (e.g., an average numbers of atomic layers). n′ is a real number that ranges from 0.5 to 3.5 (e.g., 0.5, 1, 1.5, 2, 2.5, 3 or 3.5), and m′ is a real number that ranges from 0.5 to 4.5 (e.g., 0.5, 1, 1.5, 2, 2.5, 3, 3.5, 4 or 4.5). n′ may be the same as or different from n, and m′ may be the same as or different from m. In some embodiments, the reference layer 60 may include, for example, 20 or fewer (e.g., 10 or fewer) multi-layered structures of nCo/mX, and the free layer 30 may include, for example, 20 or fewer (e.g., 10 or fewer) multi-layered structures.

Although FIG. 5 illustrates that the reference layer 60 is between the seed layer 20 and the tunnel barrier layer 50, the present invention is not limited thereto. In some embodiments, the free layer 30 may be between the seed layer 20 and the tunnel barrier layer 50.

Example embodiments are described herein with reference to the accompanying drawings. Many different forms and embodiments are possible without deviating from the scope of the present inventive concept. Accordingly, the present inventive concept should not be construed as limited to the example embodiments set forth herein. Rather, these example embodiments are provided so that this disclosure will be thorough and complete and will convey the scope of the present inventive concept to those skilled in the art. In the drawings, the sizes and relative sizes of layers and regions may be exaggerated for clarity. Like reference numbers refer to like elements throughout.

Example embodiments of the present inventive concept are described herein with reference to cross-sectional views that are schematic illustrations of idealized embodiments. As such, variations from the shapes of the illustrations as a result, for example, of manufacturing techniques and/or tolerances, are to be expected. Thus, example embodiments of the present inventive concept should not be construed as limited to the particular shapes illustrated herein but include deviations in shapes that result, for example, from manufacturing, unless the context clearly indicates otherwise.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of the stated features, steps, operations, elements and/or components, but do not preclude the presence or addition of one or more other features, steps, operations, elements, components and/or groups thereof. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the scope of the present inventive concept.

The above-disclosed subject matter is to be considered illustrative, and not restrictive, and the appended claims are intended to cover all such modifications, enhancements, and other embodiments, which fall within the scope of the inventive concept. Thus, to the maximum extent allowed by law, the scope is to be determined by the broadest permissible interpretation of the following claims and their equivalents and shall not be restricted or limited by the foregoing detailed description.

What is claimed is:

1. A magnetic tunnel junction (MTJ) structure comprising:
a first magnetic layer;
a second magnetic layer; and
a tunnel barrier layer that is between the first magnetic layer and the second magnetic layer and has a hexagonal crystal structure,
wherein the first magnetic layer comprises a multi-layered structure of nCo/mX that is magnetic at room temperature and has a hexagonal crystal structure, X is Ni, Ag, Au, Pt, Pd or Cu, n and m are each numbers of atomic layers, n ranges from 0.5 to 3.5, and m ranges from 0.5 to 4.5.

2. The MTJ structure of claim 1, wherein the first magnetic layer comprises a plurality of multi-layered structures of nCo/mX, and a number of the multi-layered structures is 20 or fewer.

3. The MTJ structure of claim 1, wherein the first magnetic layer comprises a plurality of multi-layered structures of nCo/mX, and a number of the multi-layered structures is 10 or fewer.

4. The MTJ structure of claim 1, wherein X is Ni, Ag, or Cu.

5. The MTJ structure of claim 1, wherein the tunnel barrier layer has a Wurtzite structure.

6. The MTJ structure of claim 1, wherein the tunnel barrier layer comprises AlN, GaN, CdS, CdSe, MgSe, or MgTe.

7. The MTJ structure of claim 1, wherein the tunnel barrier layer has a lattice constant in a range of from 90% to 110% of a lattice constant of the multi-layered structure of nCo/mX.

8. The MTJ structure of claim 1, wherein n ranges from 0.5 to 1.5, and m ranges from 0.5 to 1.5.

9. The MTJ structure of claim 1, wherein n ranges from 0.5 to 1.5, and m ranges from 0.5 to 4.5.

10. The MTJ structure of claim 1, wherein X is Ni, n ranges from 0.5 to 1.5, and m ranges from 0.5 to 4.5.

11. The MTJ structure of claim 1, further comprising a substrate,
wherein the first magnetic layer is between the substrate and the tunnel barrier layer.

12. The MTJ structure of claim 1, wherein the second magnetic layer comprises a multi-layered structure of n′Co/m′X′ that is magnetic at room temperature and has a hexagonal crystal structure, X′ is Ni, Ag, Au, Pt, Pd or Cu, n′ and m′ are each numbers of atomic layers, n′ ranges from 0.5 to 3.5, and m′ ranges from 0.5 to 4.5.

13. The MTJ structure of claim 12, wherein n′ n ranges from 0.5 to 1.5, and m′ ranges from 0.5 to 1.5.

14. The MTJ structure of claim 12, wherein X′ is Ni, Ag, or Cu.

15. The MTJ structure of claim 11, wherein the first magnetic layer is a reference layer.

16. The MTJ structure of claim 11, wherein the first magnetic layer is a free layer.

17. The MTJ structure of claim 16, further comprising a synthetic anti-ferromagnetic layer,
wherein the second magnetic layer contacts the synthetic anti-ferromagnetic layer.

18. A magnetoresistive random-access memory (MRAM) device comprising the MTJ structure of claim 1.

19. A magnetic sensor comprising the MTJ structure of claim 1.

20. A racetrack memory device comprising the MTJ structure of claim 1.
